(19) United States
(12) Patent Application Publication
(10) Pub. No.: US 2013/0176541 A1
(43) Pub. Date: Jul. 11, 2013

(54) OPTICAL COMPONENT, LASER LIGHT SOURCE APPARATUS AND IMAGE DISPLAY APPARATUS EACH INCLUDING THE OPTICAL COMPONENT AND MANUFACTURING METHODS THEREFOR

(71) Applicant: Panasonic Corporation, Osaka (JP)

(72) Inventors: Akira GYOUTOKU, Saga (JP); Takafumi HAMANO, Fukuoka (JP); Hiroyuki FURUYA, Kumamoto (JP)

(73) Assignee: PANASONIC CORPORATION, Osaka (JP)

(21) Appl. No.: 13/733,314

(22) Filed: Jan. 3, 2013

(30) Foreign Application Priority Data
Jan. 11, 2012 (JP) 2012-002902

(51) Int. Cl. H01S 5/10; H04N 9/31

(52) U.S. Cl. CPC H01S 5/10; H04N 9/31
USPC 353/31; 372/44.01; 428/156; 29/407.01; 216/24

(57) ABSTRACT

A laser light source apparatus is provided that can prevent an output mirror from breaking and can simplify adjustment of the attachment position of the output mirror. The laser light source apparatus includes: a semiconductor laser that outputs an excitation laser beam; a solid-state laser element that is excited by the excitation laser beam, to output a fundamental laser beam; and an output mirror that forms a resonator together with the solid-state laser element. The output mirror includes: a base part formed of a glass substrate; a convex part that is formed in the base part by dry etching; and a groove that is formed in the base part around the convex part while the dry etching proceeds. The convex part has a convex surface on which a film is formed.

### CROSS REFERENCE TO RELATED APPLICATIONS

This application is entitled to and claims the benefit of Japanese Patent Application No. 2012-002902, the disclosure of which including the specification, drawings and abstract is incorporated herein by reference in its entirety.

### BACKGROUND OF THE INVENTION

1. Field of the Invention

The present invention relates to an optical component including a semiconductor laser, a laser light source apparatus including the optical component, an image display apparatus including the optical component, and manufacturing methods therefor. In particular, the present invention relates to an optical component used for a light source in an image display apparatus, a laser light source apparatus including the optical component, and manufacturing methods therefor.

2. Description of Related Art

In recent years, technology which uses a semiconductor laser for a light source in an image display apparatus has been attracting attention. When compared with a mercury lamp that is frequently used in a conventional image display apparatus, the semiconductor laser has various advantages, including: improved color reproducibility, the ability to instantly light up, longer lifetime, the ability to reduce power consumption more efficiently, and easy miniaturization.

This type of image display apparatus requires laser beams of red, green, and blue, which are the three primary colors of light. However, semiconductor lasers that directly output a green laser beam lack high power. Accordingly, technology is known in which the laser light source apparatus used in the image display apparatus outputs an excitation laser beam from a semiconductor laser; excites a solid-state laser element with the excitation laser beam, which causes the solid-state laser element to output an infrared laser beam; and converts a wavelength of the infrared laser beam using a “wavelength converter element,” and outputs a green laser beam (see, for example, Japanese Patent Application Laid-Open No. 2008-16833).

The green laser light source apparatus includes: a semiconductor laser that outputs an excitation laser beam; the solid-state laser element that is excited by the excitation laser beam, and outputs a fundamental laser beam (infrared laser beam); a wavelength converter element that converts the wavelength of the fundamental laser beam and outputs a half-wavelength laser beam (green laser beam); and a concave mirror as an output mirror that forms a resonator together with the solid-state laser element.

In a conventional green laser light source apparatus of this type, because the output of the laser beam changes depending on an attachment position of the concave mirror with respect to an optical axis of the laser beam, disposing the concave mirror at the optimal output attachment position is desirable. Accordingly, a configuration that allows the attachment position of the concave mirror to be adjusted while monitoring the output after assembly has been conceived.

The concave mirror includes structurally sharp end parts, and the contact points of the structurally sharp end parts are held so as to abut a concave mirror supporting part. A chip/crack may arise in the end parts in an adjustment step when the concave mirror is moved with respect to the concave mirror supporting part.

Further, a change in laser output due to reflection of the concave mirror does not have any characteristic point. Even if misalignment of the concave mirror occurs, it is difficult to determine in which direction and how much the concave mirror should be adjusted.

The abovementioned problems lead to an increase in the labor hours and costs involved in the adjusting step.

An object of the claimed invention is to provide an optical component that can prevent an output mirror from breaking and that can simplify adjustment of the attachment position of the output mirror, a laser light source apparatus and an image display apparatus each including the optical component, and manufacturing methods therefor.

### SUMMARY OF THE INVENTION

The claimed invention of one embodiment provides an optical component including: a base part formed of a glass substrate; a convex part that is formed in the base part by dry etching; and a groove that is formed in the base part around the convex part while the dry etching proceeds.

The claimed invention of another embodiment provides a laser light source apparatus including: a semiconductor laser that outputs an excitation laser beam; a solid-state laser element that is excited by the excitation laser beam, to thereby output a fundamental laser beam; and an output mirror that forms a resonator together with the solid-state laser element. The output mirror provides the optical component including a film formed on a convex surface of the convex part.

The claimed invention of another embodiment provides an image display apparatus including the laser light source apparatus.

The claimed invention of another embodiment provides an image display apparatus including: a plurality of light sources; a collimator lens that converts light output from the light sources into parallel beams; a relay optical system that guides the parallel beams into the same optical path; a spatial light modulator that modulates the light beam output from the relay optical system; a projection optical system that projects the light beam modulated by the spatial light modulator to the outside of the apparatus; and a casing that supports the plurality of light sources, the collimator lens, the relay optical system, the spatial light modulator, and the projection optical system. The collimator lens includes the optical component.

The claimed invention of another embodiment provides a method of manufacturing an optical component, including: applying a resist to a glass substrate; and performing dry etching on the glass substrate that has been coated by the resist, to thereby form a convex part via the resist.

The claimed invention of another embodiment provides a method of manufacturing for a laser light source apparatus including a semiconductor laser that outputs an excitation laser beam, a solid-state laser element that is excited by the excitation laser beam to output a fundamental laser beam, a wavelength converter element that converts a wavelength of the fundamental laser beam to output a half-wavelength laser beam, an output mirror that forms a resonator together with the solid-state laser element, and a base that holds at least the output mirror, the output mirror including: a convex part, a groove formed around the convex part and a film formed on a convex surface of the convex part, the method including: attaching the output mirror to the base, wherein the attaching includes: installing the output mirror on the base, measuring a laser output of the half-wavelength laser beam at a position of the installed output mirror, and determining an attachment position of the output mirror on a basis of a measurement result of the laser output when the half-wavelength laser beam is incident on the groove.

According to the claimed invention, it is possible to prevent an output mirror from breaking and to dramatically simplify the adjustment of the attachment position of the output mirror. As a result, it is possible to significantly decrease the labor hours and to reduce the costs of the adjustment step.

### BRIEF DESCRIPTION OF DRAWINGS

FIG. 1 is an outline view illustrating an image display apparatus including a laser light source apparatus according to Embodiment 1 of the claimed invention;

FIG. 2 is a perspective view illustrating an output mirror of the laser light source apparatus according to Embodiment 1;

FIG. 3 is a schematic view illustrating a laser beam state of the laser light source apparatus according to Embodiment 1;

FIG. 4 is a perspective view illustrating the laser light source apparatus according to Embodiment 1;

FIGS. 5A to 5H are process views each schematically illustrating a method of manufacturing the output mirror of the laser light source apparatus according to Embodiment 1;

FIGS. 6A to 6C are views describing a dry etching step of the output mirror of the laser light source apparatus according to Embodiment 1;

FIGS. 7A to 7C are views describing the attachment position of the output mirror of the laser light source apparatus according to Embodiment 1;

FIGS. 8A and 8B are views describing the attachment of a concave mirror, which is a conventional output mirror, to a supporting part;

FIG. 9 is a graph illustrating a relation between an output mirror position and a laser output of the laser light source apparatus according to Embodiment 1;

FIG. 10 is a graph illustrating a relation between an output mirror parallelism and a laser output of the laser light source apparatus according to Embodiment 1;

FIG. 11 is a perspective view illustrating an output mirror of a laser light source apparatus according to Embodiment 2 of the claimed invention;

FIG. 12 is a cross-sectional view illustrating the output mirror of the laser light source apparatus according to Embodiment 2;

FIG. 13 is a schematic view for describing an operation of a green laser light source apparatus including the output mirror of the laser light source apparatus according to Embodiment 2; and

FIG. 14 is a perspective view illustrating an example in which an image display apparatus including a laser light source apparatus according to Embodiment 3 of the claimed invention is built into a notebook information processing apparatus.

### DESCRIPTION OF THE PREFERRED EMBODIMENTS

Hereinafter, embodiments of the claimed invention will be described in detail with reference to the drawings.

### Embodiment 1

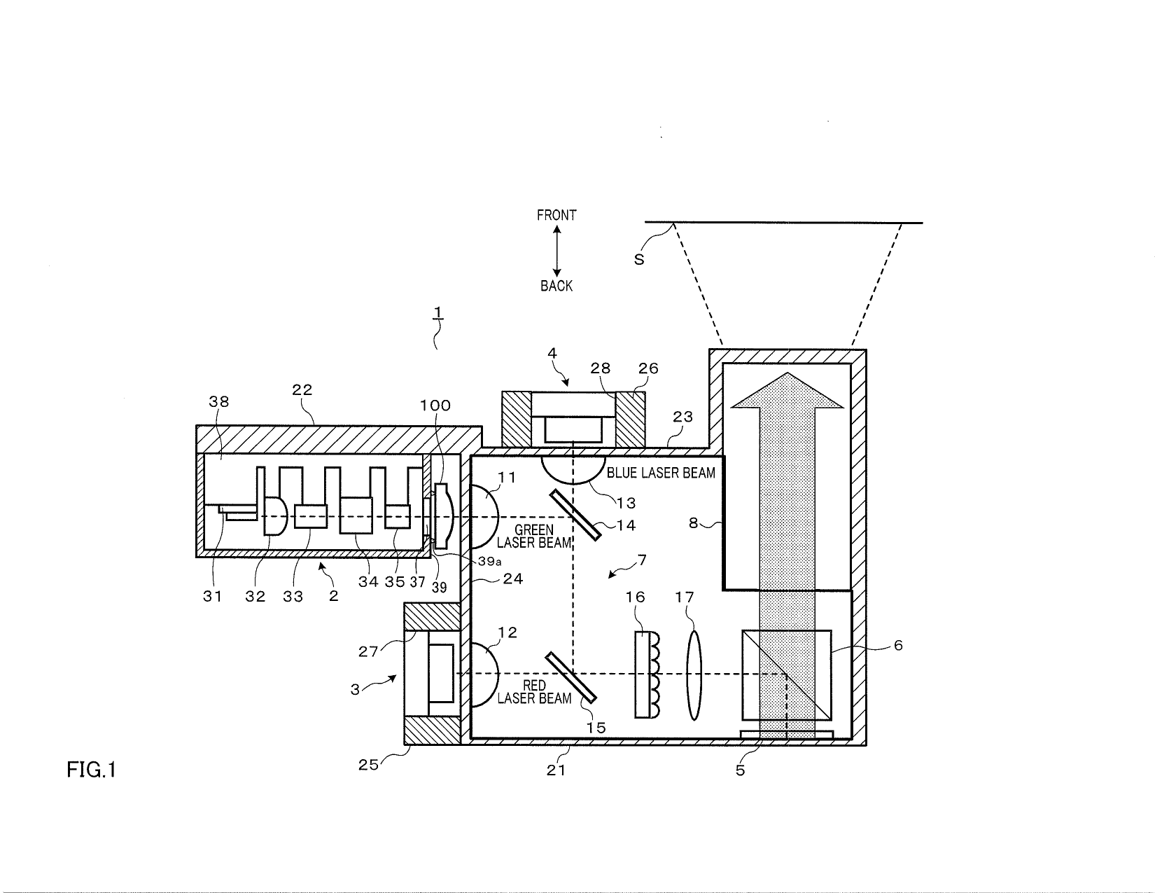

FIG. 1 is an outline view illustrating an image display apparatus including a laser light source apparatus according to Embodiment 1 of the present invention.

As illustrated in FIG. 1, image display apparatus 1 projects and displays a predetermined image onto screen S. Image display apparatus 1 includes: green laser light source apparatus 2 that outputs a green laser beam; red laser light source apparatus 3 that outputs a red laser beam; blue laser light source apparatus 4 that outputs a blue laser beam; liquid crystal reflective spatial light modulator 5 that modulates the respective laser beams from laser light source apparatuses 2 to 4 in accordance with video signals; polarization beam splitter 6 that reflects the respective laser beams from laser light source apparatuses 2 to 4, so that the laser beams are irradiated to spatial light modulator 5, and modulated laser beams emit from spatial light modulator 5 and pass through beam splitter 6; relay optical system 7 that guides the respective laser beams emitted from laser light source apparatuses 2 to 4 to polarization beam splitter 6; and projection optical system 8 that projects the modulated laser beam passed through polarization beam splitter 6 onto screen S.

Image display apparatus 1 displays a color image using a so-called field sequential system. Image display apparatus 1 sequentially outputs the respective color laser beams from laser light source apparatuses 2 to 4 in a time-division manner. An image formed by the respective color laser beams is recognized as a color image due to an optical residual image effect.

Relay optical system 7 includes: collimator lenses 11 to 13 that convert the respective color laser beams emitted from laser light source apparatuses 2 to 4 into parallel beams; first and second dichroic mirrors 14 and 15 that guide the respective color laser beams that have passed through collimator lenses 11 to 13 in predetermined directions; diffuser plate 16 that diffuses the laser beams guided by dichroic mirrors 14 and 15; and field lens 17 that converts the laser beams that have passed through diffuser plate 16 into a focused laser beam.

If a front side is the side in which a laser beam is emitted from projection optical system 8 toward screen S, a back side is the side in which the blue laser beam is emitted from blue laser light source apparatus 4. The green laser beam and the red laser beam are respectively emitted from green laser light source apparatus 2 and red laser light source apparatus 3 such that the optical axis of the green laser beam and the optical axis of the red laser beam are orthogonal to the optical axis of the blue laser beam. The blue laser beam, the red laser beam, and the green laser beam are guided into the same optical path by the two dichroic mirrors 14 and 15. In other words, the blue laser beam and the green laser beam are first guided into the same optical path by first dichroic mirror 14. Next, the blue laser beam, the green laser beam and the red laser beam are guided into the same optical path by second dichroic mirror 15.

A film is formed on first and second dichroic mirrors 14 and 15 in order to transmit and reflect laser beams of predetermined wavelengths onto a surface. First dichroic mirror 14 allows the blue laser beam to pass through and reflects the green laser beam. Second dichroic mirror 15 allows the red laser beam to pass through and reflects the blue laser beam and the green laser beam.

These optical members are supported by casing 21. Casing 21 functions as a heat dissipater that dissipates the heat generated by each of the laser light source apparatuses 2 to 4. Casing 21 is made of a material having a high thermal conductivity, such as aluminum or copper.

Green laser light source apparatus 2 is attached to attachment part 22 formed on casing 21 so as to protrude laterally. Attachment part 22 protrudes from a corner portion formed by front wall part 23 and side wall part 24, in a direction orthogonal to side wall part 24. Front wall part 23 and side wall part 24 are respectively located on the front side and a lateral side of a housing space of relay optical system 7. Red laser light source apparatus 3 is attached to an outer surface of side wall part 24 and held by holder 25. Blue laser light source apparatus 4 is attached to an outer surface of front wall part 23 and held by holder 26.

Red laser light source apparatus 3 and blue laser light source apparatus 4 are each structured in a so-called CAN package, and a laser chip that outputs a laser beam is arranged in such a way that the optical axis is located on the central axis of a can-like outer package part when supported by the system. Each laser beam is emitted through a glass window provided in an opening of the outer package part. Red laser light source apparatus 3 and blue laser light source apparatus 4 are respectively press fit into mounting holes 27 and 28 opening into holders 25 and 26, to thereby be fixed to holders 25 and 26. Heat generated by the respective laser chips of red laser light source apparatus 3 and blue laser light source apparatus 4 is transferred and dissipated to casing 21 through holders 25 and 26. Holders 25 and 26 are each made of a material having a high thermal conductivity, such as aluminum or copper.

Green laser light source apparatus 2 includes: semiconductor laser 31 that outputs an excitation laser beam; fast-axis collimator (FAC) lens 32 and rod lens 33 that are condenser lenses that condense the excitation laser beam output from semiconductor laser 31; solid-state laser element 34 that is excited by the excitation laser beam to output a fundamental laser beam (infrared laser beam); wavelength converter element (optical element) 35 that converts the wavelength of the fundamental laser beam to output a half-wavelength laser beam (green laser beam); output mirror 100 that forms a resonator together with solid-state laser element 34; glass cover 37 that blocks the excitation laser beam and the fundamental wavelength laser beam from leaking; base 38 that supports the respective parts; and cover 39 that covers the respective parts. Cover 39 includes protrusion 39a, and output mirror 100 is mounted on protrusion 39a.

Green laser light source apparatus 2 is fixed by attaching base 38 to attachment part 22 of casing 21. A gap having a predetermined width (e.g., equal to or less than 0.5 mm) is formed between green laser light source apparatus 2 and side wall part 24 of casing 21. This gap prevents heat generated by green laser light source apparatus 2 from being easily transmitted to red laser light source apparatus 3. As a result, an increase in the temperature of red laser light source apparatus 3 is suppressed, and red laser light source apparatus 3 demonstrating poor thermal behavior can be stably operated. Further, in order to insure a predetermined margin (e.g., about 0.3 mm) to adjust the optical axis of red laser light source apparatus 3, a gap having a predetermined width (e.g., equal to or more than 0.3 mm) is provided between green laser light source apparatus 2 and red laser light source apparatus 3.

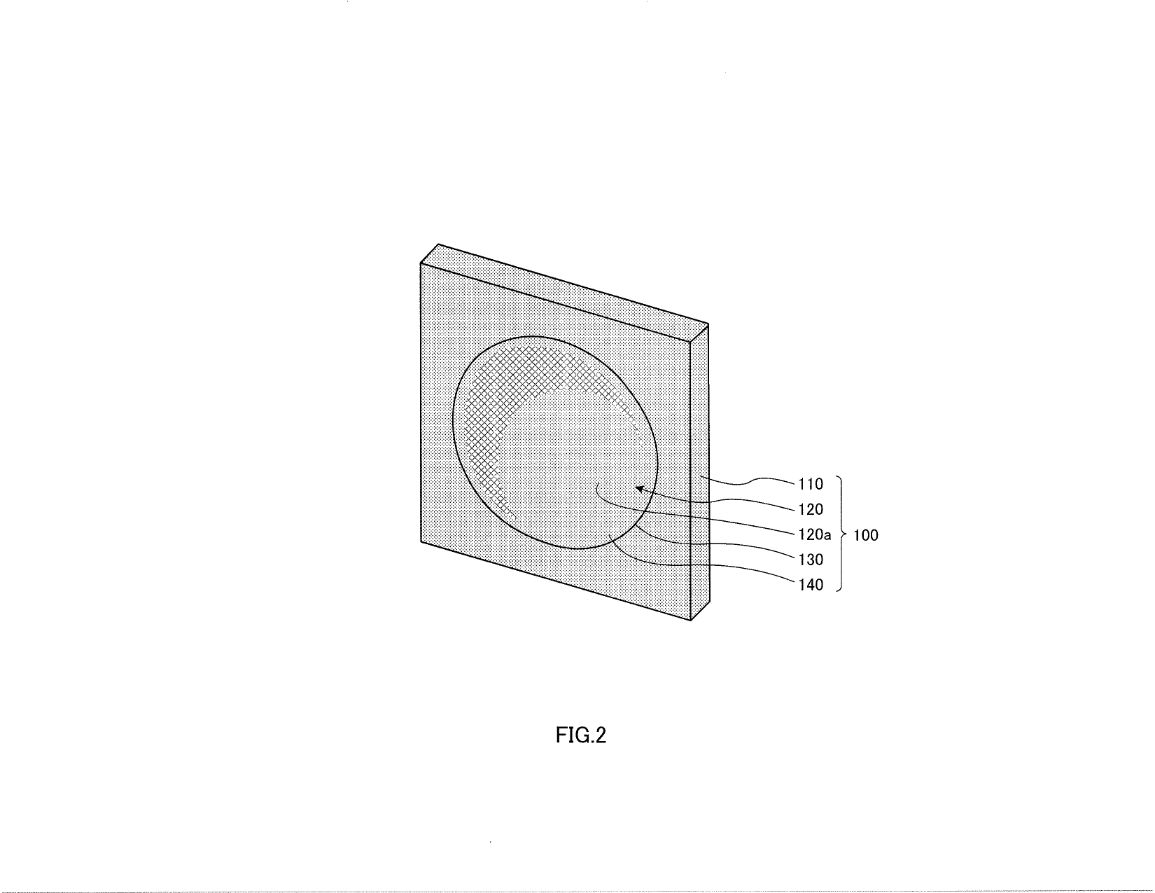

FIG. 2 is a perspective view illustrating output mirror 100.

As illustrated in FIG. 2, output mirror 100 is a convex lens mirror.

Output mirror 100 includes: base part 110 formed of a glass substrate; circular convex part 120 that is formed in base part 110 by dry etching; groove 130 that is formed in base part 110 around convex part 120 while the dry etching proceeds; and film 140 formed on convex surface 120a of convex part 120.

Convex part 120 has a convex shape that cannot actually be distinguished by naked eyes.

Groove 130 has a depth and a width that are different depending on the etching conditions and the radius of curvature of a resist. For example, groove 130 has an approximate depth of 1 μm or less and a width of several micrometers or less.

Film 140 functions to provide high reflectivity to a fundamental wavelength laser beam with a wavelength of 1,064 nm and functions to provide antireflectivity to a half-wavelength laser beam with a wavelength of 532 nm.

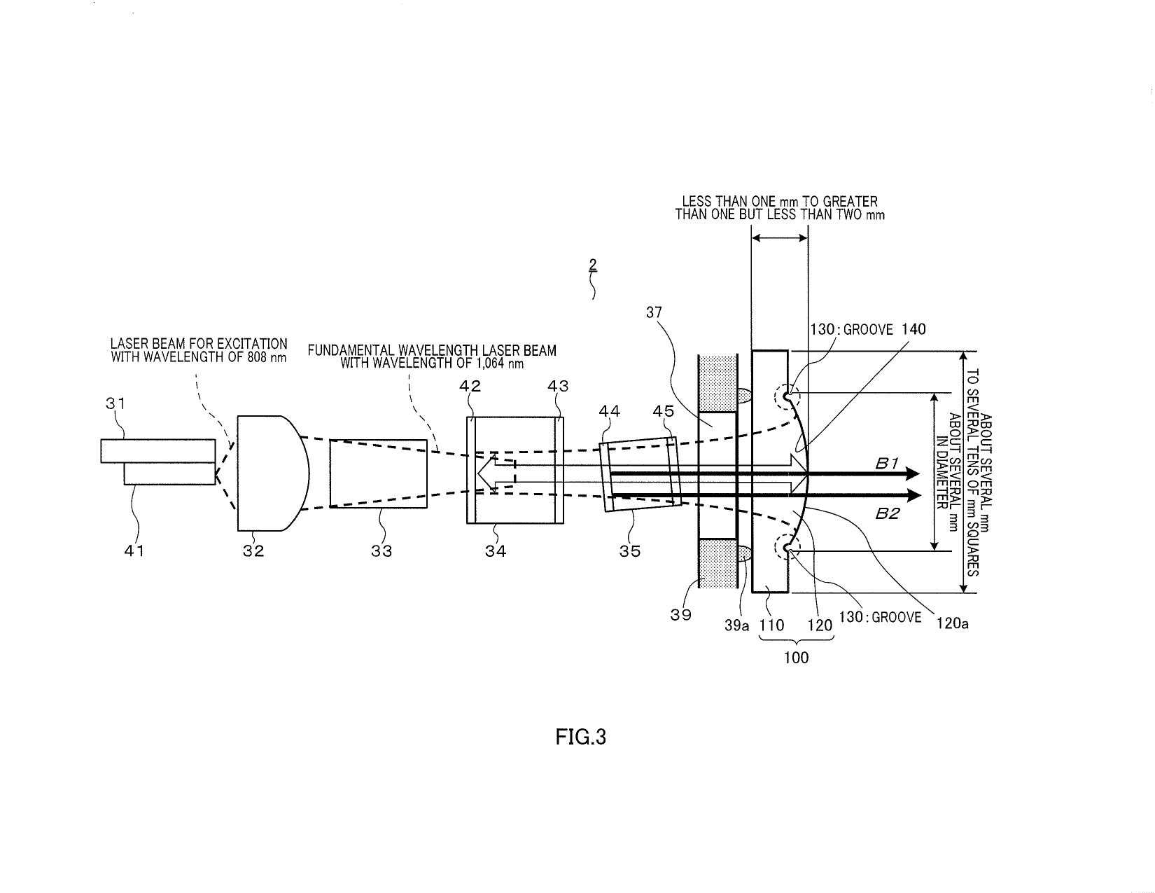

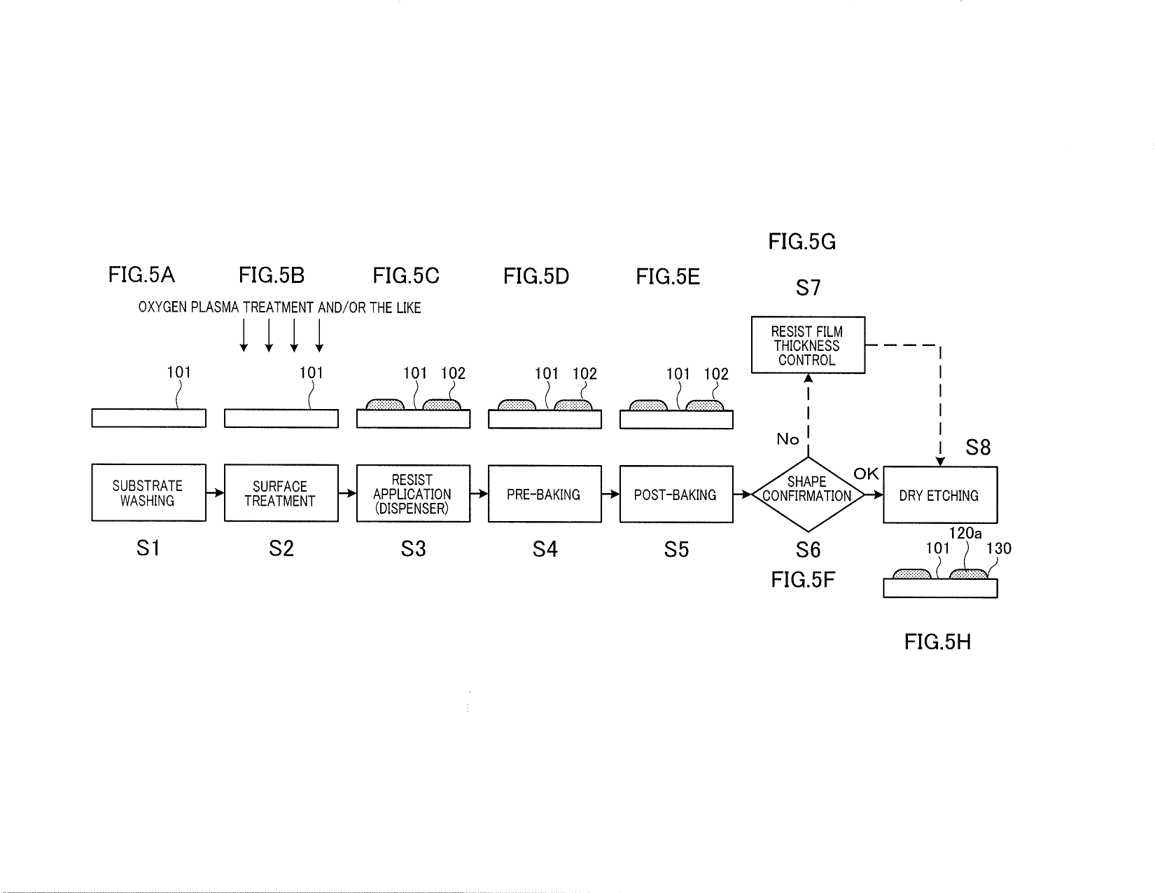

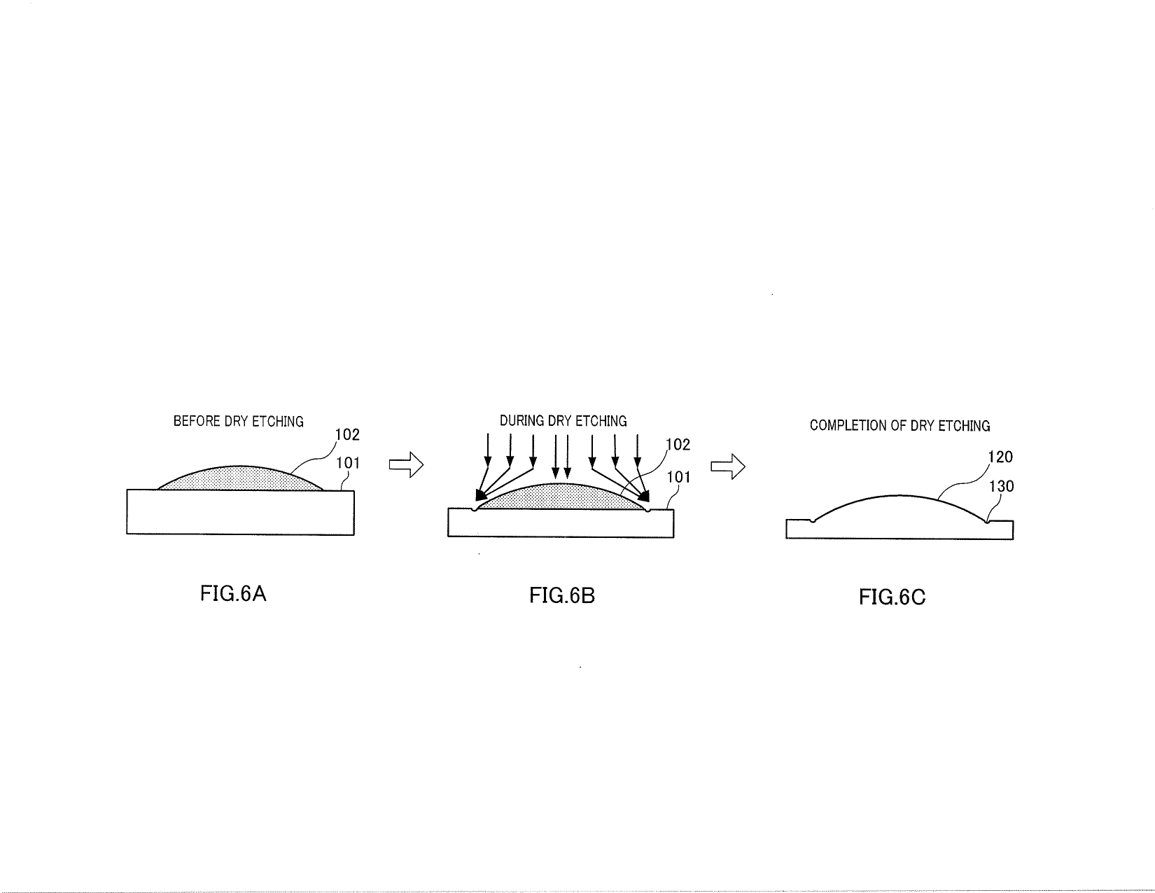

Output mirror 100 is set such that convex part 120 is located on the side opposite to the side facing wavelength converter element 35 (see FIG. 1). Using this configuration, the fundamental wavelength laser beam with a wavelength of 1,064 nm is resonated and amplified between film 42 (see FIG. 3) of solid-state laser element 34 and film 140 formed on convex surface 120a of output mirror 100. The details of a method of manufacturing output mirror 100 will be described hereinafter with reference to FIGS. 5A to 5H and FIGS. 6A to 6C.

FIG. 3 is a schematic view illustrating the state of the laser beams of green laser light source apparatus 2.

As illustrated in FIG. 3, laser chip 41 of semiconductor laser 31 outputs an excitation laser beam with a wavelength of 808 nm. FAC lens 32 reduces spreading (in a direction orthogonal to the optical axis direction and along the plane of FIG. 3) of the fast axis of the laser beam. Rod lens 33 reduces spreading (in a direction orthogonal to the plane of FIG. 3) of the slow axis of the laser beam.

Solid-state laser element 34 is a so-called solid-state laser crystal, which is excited by the excitation laser beam with a wavelength of 808 nm that has passed through rod lens 33, and which outputs the fundamental wavelength laser beam (infrared laser beam) with a wavelength of 1,064 nm. This solid-state laser element 34 is made of an inorganic optically active substance (crystal) made of Y (yttrium) VO4 (vanadate) doped with Nd (neodymium). More specifically, base material YVO4 is doped with fluorescent element Nd+3, and Y is substituted with fluorescent element Nd+3.

Film 42 is formed on a side of solid-state laser element 34 facing rod lens 33, and film 42 functions to provide antireflectivity to the excitation laser beam with a wavelength of 808 nm and high reflectivity to the fundamental wavelength laser beam with a wavelength of 1,064 nm and the half-wavelength laser beam with a wavelength of 532 nm. Film 43 is formed on another side of solid-state laser element 34 facing wavelength converter element 35, and film 43 functions to provide antireflectivity to the fundamental wavelength laser beam with a wavelength of 1,064 nm and the half-wavelength laser beam with a wavelength of 532 nm.

Wavelength converter element 35 has a substantially cuboid shape, and is a so-called second harmonics generation (SHG) element. Wavelength converter element 35 converts the wavelength of the fundamental wavelength laser beam (infrared laser beam) with a wavelength of 1,064 nm output from solid-state laser element 34, and generates the half-wavelength laser beam (green laser beam) with a wavelength of 532 nm.

Film 44 is formed on a side of wavelength converter element 35 facing solid-state laser element 34, and film 44 functions to provide antireflectivity to the fundamental wavelength laser beam with a wavelength of 1,064 nm and high reflectivity to the half-wavelength laser beam with a wavelength of 532 nm. Film 45 is formed on another side of wavelength converter element 35 facing output mirror 100, and film 45 functions to provide antireflectivity to the fundamental wavelength laser beam with a wavelength of 1,064 nm and the half-wavelength laser beam with a wavelength of 532 nm.

Output mirror 100 has convex surface 120a on the side opposite to the side facing wavelength converter element 35. Film 140 is formed on convex surface 120a, and film 140 functions to provide high reflectivity to the fundamental wavelength laser beam with a wavelength of 1,064 nm and antireflectivity to the half-wavelength laser beam with a wavelength of 532 nm. Using this configuration, the fundamental wavelength laser beam with a wavelength of 1,064 nm is resonated and amplified between film 42 of solid-state laser element 34 and film 140 of output mirror 100.

Output mirror 100 has a rear surface that is not convex, but flat. A film having an antireflection function for a wavelength of 1,064 nm and a wavelength of 532 nm is formed on the rear surface.

Wavelength converter element 35 converts part of the fundamental wavelength laser beam with a wavelength of 1,064 nm that is incident from solid-state laser element 34, into the half-wavelength laser beam with a wavelength of 532 nm. The other part of the fundamental wavelength laser beam with a wavelength of 1,064 nm that has passed through wavelength converter element 35 without being converted is reflected on output mirror 100, is incident on wavelength converter element 35 again, and is converted into the half-wavelength laser beam with a wavelength of 532 nm. This half-wavelength laser beam with a wavelength of 532 nm is reflected on film 44 of wavelength converter element 35, and is emitted from wavelength converter element 35.

The laser beam that is incident on wavelength converter element 35 from solid-state laser element 34, subjected to wavelength conversion by wavelength converter element 35 and emitted from wavelength converter element 35 is beam B1; and the laser beam that is reflected once on output mirror 100, incident on wavelength converter element 35, reflected on film 44, and emitted from wavelength converter element 35 is beam B2. In a state where beam B1 and beam B2 overlap with each other, the half-wavelength laser beam with a wavelength of 532 nm and the fundamental wavelength laser beam with a wavelength of 1,064 nm interfere with each other, resulting in a decrease in output.

In FIG. 3, wavelength converter element 35 is inclined towards the optical axis direction, and laser beams B1 and B2 are prevented from overlapping with each other by the refractive actions of the incident surface and the exit surface. Accordingly, interference is prevented between the half-wavelength laser beam with a wavelength of 532 nm and the fundamental wavelength laser beam with a wavelength of 1,064 nm. Using such a configuration, the decrease in output of the laser beam can be avoided.

In order to prevent the excitation laser beam with a wavelength of 808 nm and the fundamental wavelength laser beam with a wavelength of 1,064 nm from leaking to the exterior portion, a film that does not allow laser beams to pass through is formed on glass cover 37, which is illustrated in FIG. 1.

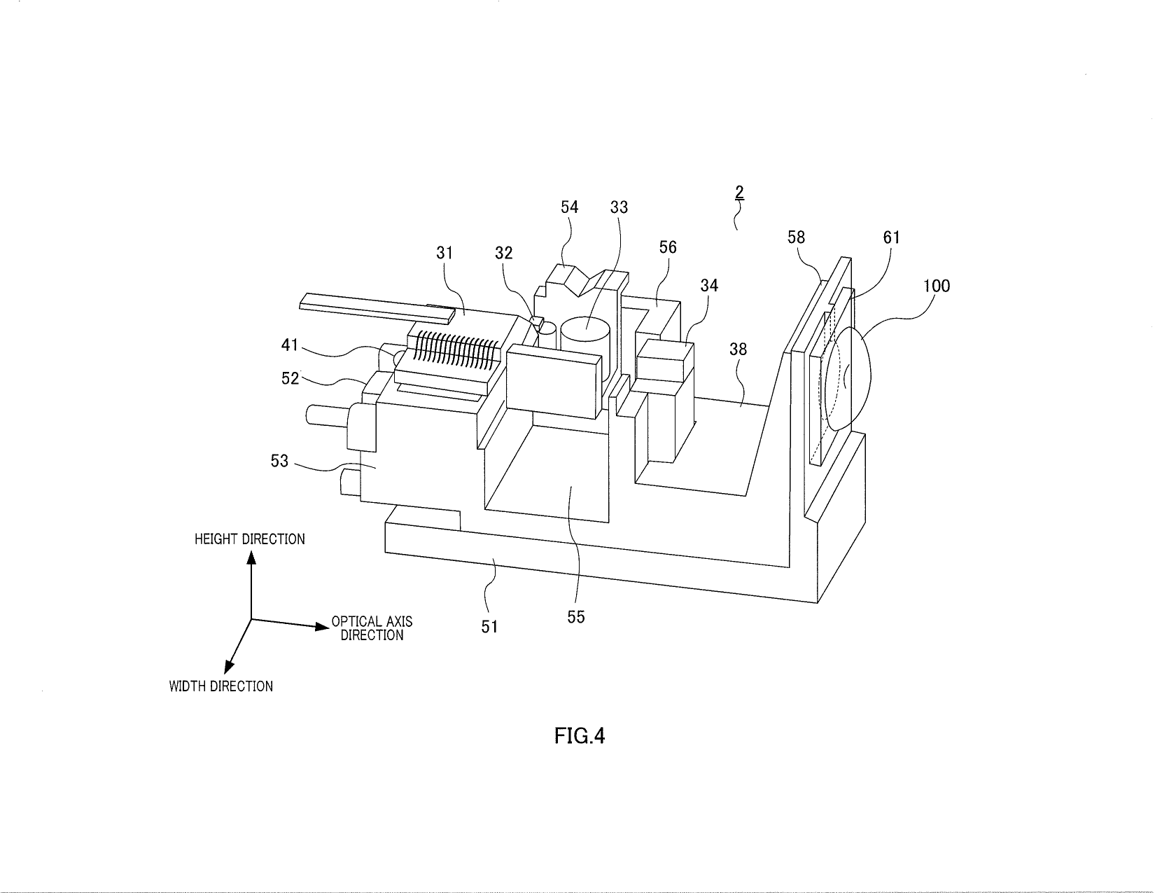

FIG. 4 is a perspective view illustrating green laser light source apparatus 2.

As illustrated in FIG. 4, semiconductor laser 31, FAC lens 32, rod lens 33, solid-state laser element 34, wavelength converter element 35 (not illustrated), and output mirror 100 are integrally supported by base 38. Bottom surface 51 of base 38 is parallel to the optical axis direction. A direction orthogonal to bottom surface 51 of base 38 is the height direction; and a direction orthogonal to the height direction and the optical axis direction is the width direction. Further, the side closer to bottom surface 51 of base 38 is the bottom; and the side opposite to bottom surface 51 is the top. The above description does not necessarily coincide with the actual top-bottom direction of the apparatus.

Semiconductor laser 31 is composed of laser chip 41 that outputs a laser beam mounted on mount member 52. Laser chip 41 has an elongated strip shape in the optical axis direction, and is fixed at a substantially central position in the width direction on a surface of plate-like mount member 52, in the state where the light exiting surface of laser chip 41 faces FAC lens 32. The semiconductor laser 31 is fixed to base 38 through attachment member 53. The attachment member 53 is made of a metal having a high thermal conductivity, such as copper or aluminum, whereby the heat generated by laser chip 41 can be transferred and dissipated to base 38.

FAC lens 32 and rod lens 33 are held by condenser lens holder 54. The condenser lens holder 54 is supported by supporting part 55 that is integrally formed in base 38. Condenser lens holder 54 is movably coupled to supporting part 55 in the optical axis direction, to thereby enable adjustment of the position of condenser lens holder 54, i.e., enable the adjustment of the positions of FAC lens 32 and rod lens 33, in the optical axis direction. FAC lens 32 and rod lens 33 are fixed to condenser lens holder 54 using an adhesive prior to position adjustment work, and condenser lens holder 54 and supporting part 55 are fixed to each other using an adhesive after the position adjustment is performed.

Solid-state laser element 34 is supported by solid-state laser element supporting part 56 integrally formed in base 38.

Wavelength converter element 35 (not illustrated) is held by wavelength converter element holder 58. In order to enable adjustment of the position of wavelength converter element 35 in the width direction and adjustment of the angle of inclination to the optical axis direction, wavelength converter element holder 58 is installed on base 38 so as to be movable in the width direction and turnable around an axis substantially orthogonal to the optical axis direction. Wavelength converter element 35 is fixed to wavelength converter element holder 58 using an adhesive before the position adjustment is performed, and wavelength converter element holder 58 and base 38 are fixed to each other using an adhesive after the position adjustment is performed.

Output mirror 100 is supported by output mirror supporting part 61 that is integrally formed in base 38.

For example, a UV cure adhesive is suitable for the adhesive used to fix the above-mentioned members, such as wavelength converter element holder 58 and base 38.

FIGS. 5A to 5H are process views that schematically describe the method of manufacturing output mirror 100.

Step S1: Substrate Washing Step (See FIG. 5A)

Glass substrate 101 that is to become a substrate of output mirror 100 is cleaned. Examples of the substrate washing include ultrasonic washing and cloth wiping.

Step S2: Surface Treatment Step (See FIG. 5B)

The surface of glass substrate 101 is subjected to surface treatment after the washing, e.g., oxygen plasma treatment or ozone treatment. The surface treatment is a pretreatment step for enhancing the adhesiveness of a resist to be applied.

Step S3: Resist Application Step (See FIG. 5C)

Specifically, resist 102 is applied using a dispenser. In the present embodiment, AZ-6112 produced by AZ Electronic Materials is used for resist 102, which is applied using the dispenser.

Step S4: Pre-Baking Step (See FIG. 5D)

Glass substrate 101 to which resist 102 is applied is pre-baked at a temperature of about 70° C. to 90° C. In the present embodiment, glass substrate 101 is pre-baked at 80° C. The pre-baking evaporates the solvent remaining in the resist film applied to glass substrate 101 that is a treatment target substrate, to thereby enhance the adhesiveness between the resist film and the substrate. The pre-baking is performed at a relatively low temperature, so that the resist material does not react.

Step S5: Post-Baking Step (See FIG. 5E)

Resist 102 and glass substrate 101 are post-baked at a temperature of about 100° C. to 150° C. after the pre-baking. In the present embodiment, resist 102 and glass substrate 101 are post-baked at 150° C. The post-baking further enhances curing of the resist film pattern and the adhesiveness between the resist film pattern and the substrate. The post-baking is a heat treatment performed at a resist tolerable temperature.

Step S6: Resist Shape Confirmation Step (See FIG. 5F)

The shape of resist 102 after the post-baking is confirmed. In the present embodiment, the resist shape at this time is 1.5 to 4 mm in diameter, 40 to 70 μm in film thickness, and 5 to 15 mm in radius of curvature (R). Based on the results of the resist shape confirmation, when the shape of resist 102 is within a predetermined range, the process goes to a dry etching step (see FIG. 5H). When the shape of resist 102 is not within the predetermined range, the process goes to a resist film thickness controlling step (see FIG. 5G).

Step S7: Resist Film Thickness Controlling Step (See FIG. 5G)

The resist film thickness is controlled such that the resist shape formed by dry etching is within the predetermined range. Specifically, only the resist itself is etched by dry etching such as oxygen plasma treatment, in order to control film thickness. In the present embodiment, the resist shape at this time is 2 mm in diameter, 12 μm in film thickness, and 40 mm in R.

Step S8: Dry Etching Step (See FIG. 5H)

The substrate is etched using a dry etching apparatus such as an RIE or ICP apparatus. Although both resist 102 and glass substrate 101 are etched by dry etching, resist 102 serves as a mask for glass substrate 101, which allows a convex shape to be formed on glass substrate 101.

After the dry etching, convex part 120 and groove 130 surrounding convex part 120 are formed on glass substrate 101. A plurality of convex parts 120 and grooves 130 are formed in an array at resist intervals. After that, film 140 for laser is formed on the surface of glass substrate 101 (convex surface 120a of convex part 120), and glass substrate 101 is cut for completion of output mirror 100.

FIGS. 6A to 6C are views for describing the dry etching step of output mirror 100.

FIG. 6A illustrates resist 102 and glass substrate 101 before the dry etching. As illustrated in FIG. 6B, resist 102 is mainly etched during dry etching. For example, in the case of dry etching with argon, resist 102 and glass substrate 101 are etched. In the case of dry etching with oxygen, only resist 102 is etched, while glass substrate 101 is not etched. Dry etching with oxygen is effective to form an output mirror including a convex part with a large curvature.

As indicated by arrows in FIG. 6B, in the case of the dry etching with argon, argon plasma hit against resist 102, move along the surface of resist 102, concentrate in a peripheral portion of resist 102, and form groove 130. Further, as a result of the shape, the etching rate of the end parts of resist 102 is increased by concentrating the plasma on the edge part of resist 102, so that groove 130 is formed.

As illustrated in FIG. 6C, when resist 102 is entirely etched, dry etching is completed. As described above, film 140 is formed on the surface of glass substrate 101 (convex surface 120a of convex part 120), and glass substrate 101 is cut for completion of output mirror 100.

Completed output mirror 100 includes: base part 110 that is formed of glass substrate 101; circular convex part 120 that is formed in base part 110 by dry etching; groove 130 that is formed in base part 110 around convex part 120 while the dry etching proceeds; and film 140 formed on convex surface 120a of convex part 120. In particular, as illustrated in FIG. 6C, groove 130 is formed around convex part 120 at the time of dry etching completion, when resist 102 is entirely etched. Groove 130 has a different depth and a width depending on the etching conditions or the radius of curvature of the resist. For example, groove 130 has a depth of 1 μm or less and a width of several tens of micrometers or less.

Further, the film that provides the function of antireflectivity to a wavelength of 1,064 nm and a wavelength of 532 nm is formed on the rear surface of output mirror 100. The rear surface is not convex, but flat.

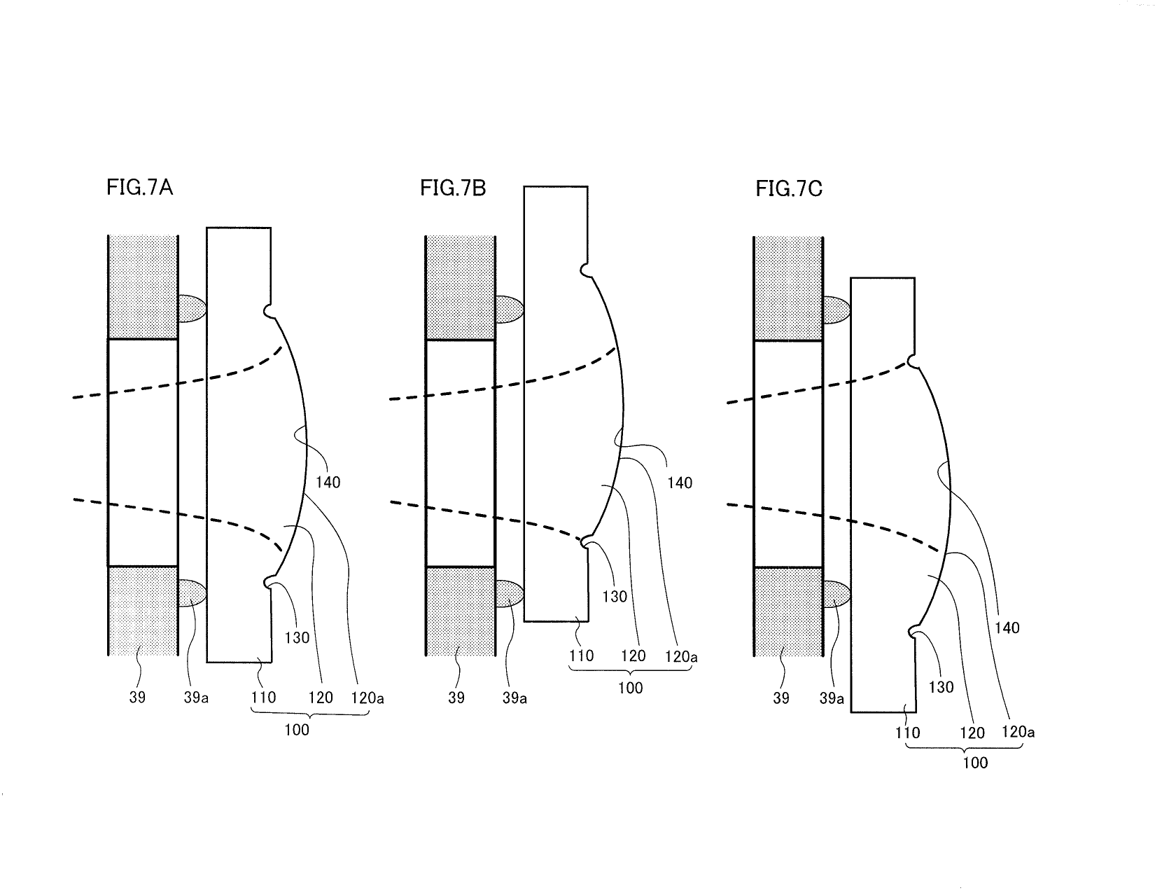

FIGS. 7A to 7C are views for describing the attachment position of output mirror 100. FIG. 7A illustrates the case where output mirror 100 is appropriately attached to output mirror supporting part 61 (see FIG. 4), and FIGS. 7B and 7C each illustrate the case where output mirror 100 is misaligned and attached to output mirror supporting part 61. In FIGS. 7A to 7C, the broken lines each show the fundamental wavelength laser beam with a wavelength of 1,064 nm.

As illustrated in FIG. 7A, output mirror 100 is appropriately attached to and supported by output mirror supporting part 61 (see FIG. 4). In this case, the incident fundamental wavelength laser beam passes through the center of the optical axis of output mirror 100, and is reflected on laser film 140 formed on convex surface 120a of convex part 120.

As illustrated in FIG. 7B and FIG. 7C, output mirror 100 may be misaligned and attached to output mirror supporting part 61, as the result of an attachment error and/or the like. In the case where output mirror 100 is misaligned and attached to output mirror supporting part 61, the incident fundamental wavelength laser beam passes through a position off the center of the optical axis of output mirror 100. Accordingly, part of the incident fundamental wavelength laser beam is not reflected on laser film 140 in an appropriate direction. In the cases illustrated in FIG. 7B and FIG. 7C where the attachment position of output mirror 100 is so remarkably misaligned that the incident fundamental wavelength laser beam reaches beyond the end part of convex part 120 of output mirror 100, the incident beam that reaches beyond the end part of convex part 120 is not reflected on laser film 140. In this way, in the case where output mirror 100 is misaligned and attached, the output efficiency of semiconductor laser 31 is remarkably lower. A product having a degree of misalignment equal to or more than a predetermined range is excluded as a defective in an examination step.

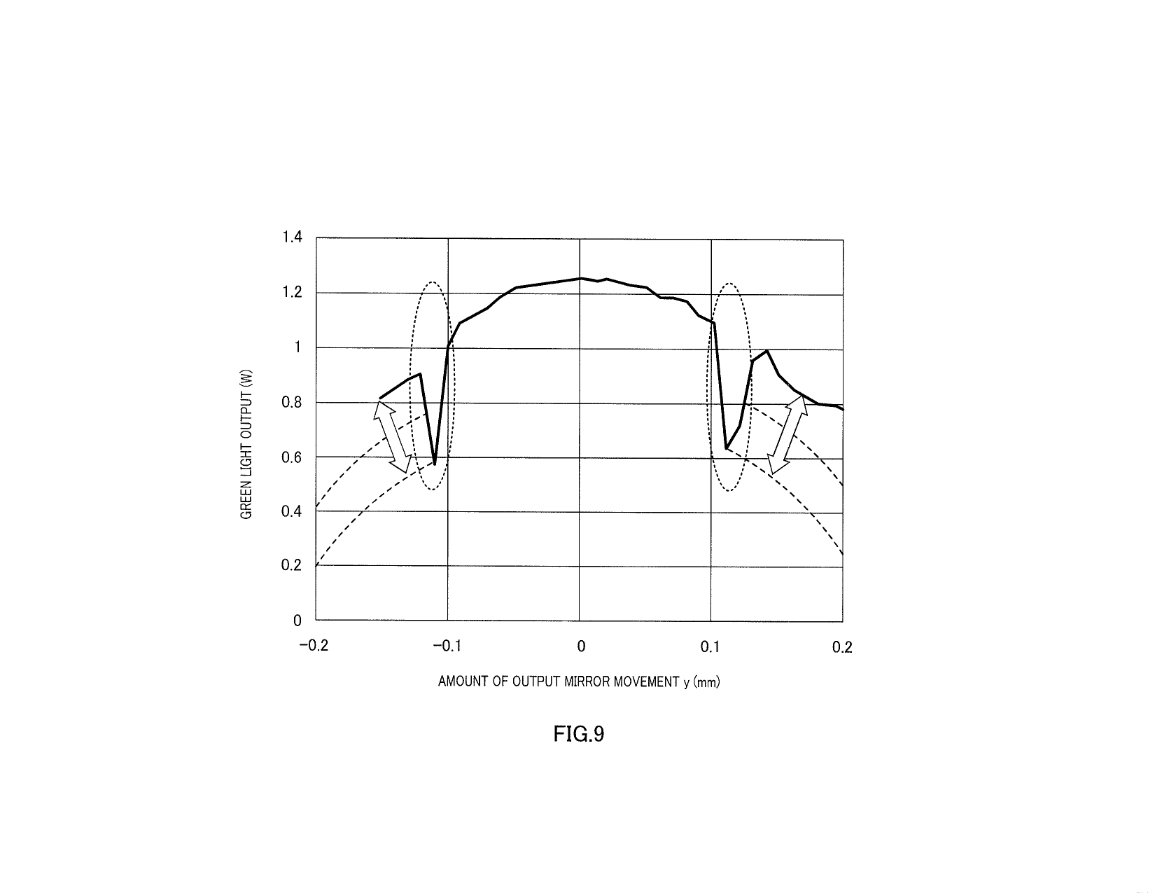

In the present embodiment, because output mirror 100 includes groove 130 formed around convex part 120, output mirror 100 can be easily attached to an appropriate position of the output mirror supporting part 61 (see FIG. 4) as described hereinafter with reference to FIGS. 7A to 7C and FIG. 9.

On the other hand, attachment of a conventional output mirror to an output mirror supporting part is not so easily accomplished.

Hereinafter, a description will be provided regarding reasons why the attachment and positioning of a conventional concave mirror to the supporting part are difficult and why the attachment and positioning of output mirror 100 to output mirror supporting part 61 (see FIG. 4) described in the present embodiment are easily accomplished.

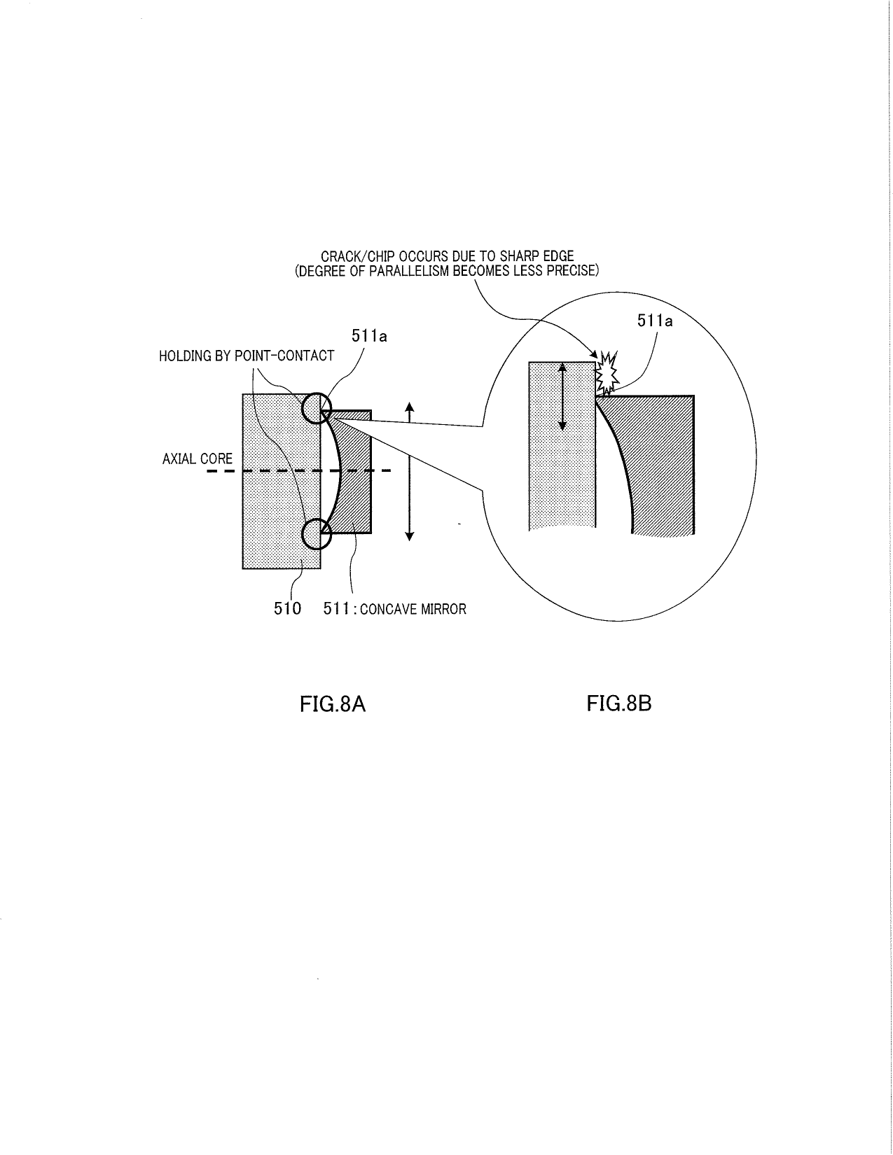

FIGS. 8A and 8B are views describing the attachment of the concave mirror that is the conventional output mirror, to the supporting part. FIG. 8A is a cross-sectional view illustrating the concave mirror and the supporting part form an enlarged perspective, and FIG. 8B is an enlarged view illustrating a main portion of FIG. 8A.

As illustrated in FIG. 8A, in the conventional example, concave mirror 511 that forms a resonator is positioned and attached to base-coated concave mirror supporting part 510. Concave mirror 511 is held with both end parts 511a in point contact with concave mirror supporting part 510. Further, concave mirror 511 should be attached to the axial core of concave mirror supporting part 510. In order to attach concave mirror 511 to the axial core of concave mirror supporting part 510, the laser output is monitored after assembly of a semiconductor laser, and concave mirror 511 is moved with respect to concave mirror supporting part 510 on the basis of the monitoring results.

(1) On the other hand, a change in laser output due to reflection of concave mirror 511 does not have any characteristic points. Even if misalignment of concave mirror 511 occurs, it is difficult to determine in which direction and how much concave mirror 511 should be adjusted. In other words, because the structure of the concave mirror 511 allows for a certain amount of reflection when the concave mirror 511 is slightly misaligned and the change in reflection efficiency occurs slowly, it is difficult to determine the amount of adjustment required. If the adjustment is insufficient, the efficiency of the semiconductor laser decreases.

(2) Concave mirror 511 is held in point contact with base-coated concave mirror supporting part 510. In the structure of concave mirror 511 shown in FIG. 8B, both end parts 511a of concave mirror 511 that are held in point contact are sharp. Accordingly, as indicated by an arrow of FIG. 8B, when concave mirror 511 is moved for adjustment with respect to concave mirror supporting part 510, end parts 511a may crack/chip. Further, a coated surface of concave mirror supporting part 510 may peel off. When a crack, chip and/or the like occurs, parallelism becomes less precise. Further, a broken piece and/or the like may get mixed into the cover.

(3) The abovementioned problems (1) and (2) make the adjusting step more complicated, resulting in an increase in costs.

FIG. 9 is a graph illustrating a relation between the output mirror position of output mirror 110 and the laser output according to Embodiment 1. The vertical axis thereof shows the green light output (W), and the horizontal axis thereof shows the amount of output mirror movement y (mm).

As illustrated in FIG. 3 and FIGS. 7A to 7C, output mirror 100 includes groove 130 formed around convex part 120.

The characteristic graph illustrated in FIG. 9 is obtained by moving output mirror 100 from the position of FIG. 7A to the position of FIG. 7B or FIG. 7C. The portions surrounded by broken lines in FIG. 9 each show the laser output when the fundamental wavelength laser beam is incident on groove 130. In particular, when the laser beam is incident on a central portion of groove 130, the laser output appears as a point of inflection shown in a sharp wedge-like graph. The above laser output is obtained when output mirror 100 is in the state shown in FIG. 7B or FIG. 7C.

Further, the arrows in FIG. 9 each indicate that when a lens peripheral portion outside of the center of groove 130 overlaps with the beam, the output fluctuates, depending on the size of the beam diameter. The light output is lower as the beam diameter decreases. Accordingly, if groove 130 overlaps with a region of the infrared light beam for excitation, the laser output shows a characteristic change, and appears as a point of inflection. The direction of movement and the amount of movement of output mirror 100 can be determined by detecting the point of inflection. In other words, by detecting the point of inflection, a person adjusting the optical axis would be able to recognize that the optical axis of each of light source apparatuses 2 to 4 significantly deviates from the adjustment range, and thus immediately be able to make a readjustment in the opposite direction. Accordingly, because the movement direction and the amount of movement of output mirror 100 have been clarified, adjusting the attachment position of output mirror 100 is extremely easy.

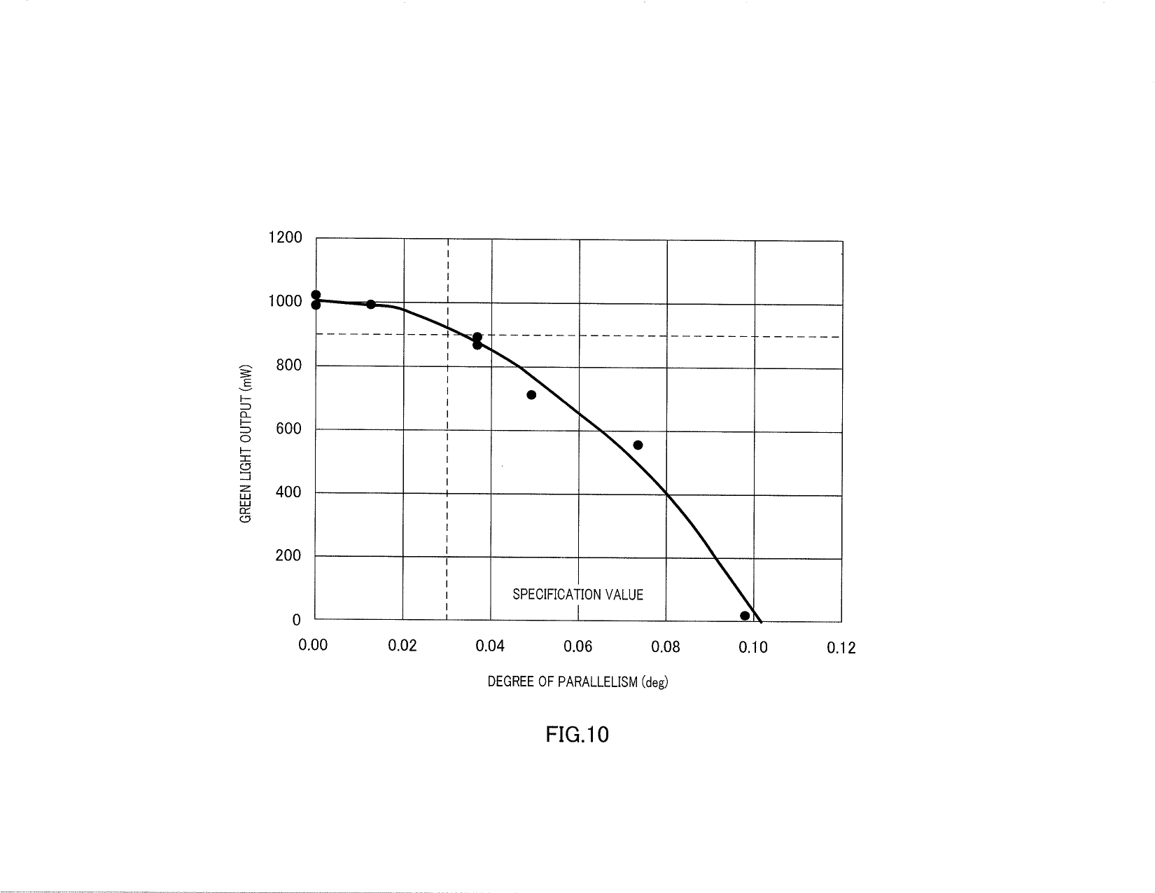

FIG. 10 is a graph illustrating a relationship between the degree of parallelism of the output mirror and the laser output. The vertical axis shows the green light output (mW), and the horizontal axis shows the output mirror parallelism (deg). In FIG. 10, the broken lines illustrate that an output of 90% or higher cannot be obtained unless the degree of parallelism of the output mirror is equal to or less than 0.03 (deg).

As illustrated in FIG. 10, an output of 90% or higher cannot be obtained unless the degree of parallelism of the output mirror is equal to or less than 0.03 (deg). As described above, in the case where output mirror 100 is in the state shown in FIG. 7B or FIG. 7C, the laser output when the laser beam is incident on the central portion of groove 130 appears as the point of inflection in the sharp wedge-like graph.

In the present embodiment, because output mirror 100 includes groove 130 formed around convex part 120, the attachment position of output mirror 100 can be determined on the basis of the point of inflection of the laser output when the laser beam is incident on the central portion of groove 130. Accordingly, the degree of parallelism of the output mirror can be maintained within a predetermined range by adjusting the attachment position of output mirror 100.

As described above in detail, green laser light source apparatus 2 according to the present embodiment includes: semiconductor laser 31 that outputs the excitation laser beam; solid-state laser element 34 that is excited by the excitation laser beam to output the fundamental laser beam (infrared laser beam); wavelength converter element 35 that converts the wavelength of the infrared laser beam output from the solid-state laser element to output the green laser beam; and output mirror 100 that forms the resonator together with solid-state laser element 34. Output mirror 100 includes: base part 110 formed of the glass substrate; convex part 120 that is formed in base part 110 by dry etching; groove 130 that is formed in base part 110 around convex part 120 while dry etching proceeds; and film 140 formed on convex surface 120a of convex part 120.

Further, the manufacturing method of output mirror 100 includes: applying resist 102 to glass substrate 101; and performing the dry etching on resist coated glass substrate 101, to thereby form convex part 120 via resist 102.

Moreover, the attaching of output mirror 100 includes: installing output mirror 100 on base 38; measuring the laser output at the position of the installed output mirror 100; and determining the attachment position of output mirror 100 on the basis of a measurement result of the laser output when the laser beam is incident on groove 130.

In the present embodiment, because output mirror 100 is a convex lens mirror, unlike the conventional concave mirror, output mirror 100 can avoid being held in point-contact at the sharp end parts, and thus breakage of the output mirror at the time of attachment can be prevented.

Further, in the present embodiment, because output mirror 100 includes groove 130 formed around convex part 120, misalignment of the concave mirror can be easily determined, and the adjustment of the attachment position of the output mirror can be dramatically simplified. As a result, it is possible to make adjusting of the output mirror significantly easier, resulting in a decrease in costs.

Further, in the present embodiment, the production of output mirror 100 including convex part 120 and groove 130 is also very easy. In other words, resist 102 is typically applied to glass substrate 101 and dry etching is performed on the glass substrate 101, to thereby form convex part 120 and groove 130 via resist 102. Technology for forming convex part 120 by creating a convex surface shape on the resist using a simple technique of applying surface tension alone and performing dry etching via resist 102 utilizing such an effect, without the use of a complicated photolithography technique, was first discovered by the inventors of the claimed invention. Thus, a new step for forming groove 130 is unnecessary. Moreover, a polishing step is necessary to manufacture the conventional concave mirror, and thus a reduction in component costs is difficult. With regard to the manufacturing method of output mirror 100, the decrease in the abovementioned manufacturing costs results from a synergistic effect in manufacturing simplicity.

### Embodiment 2

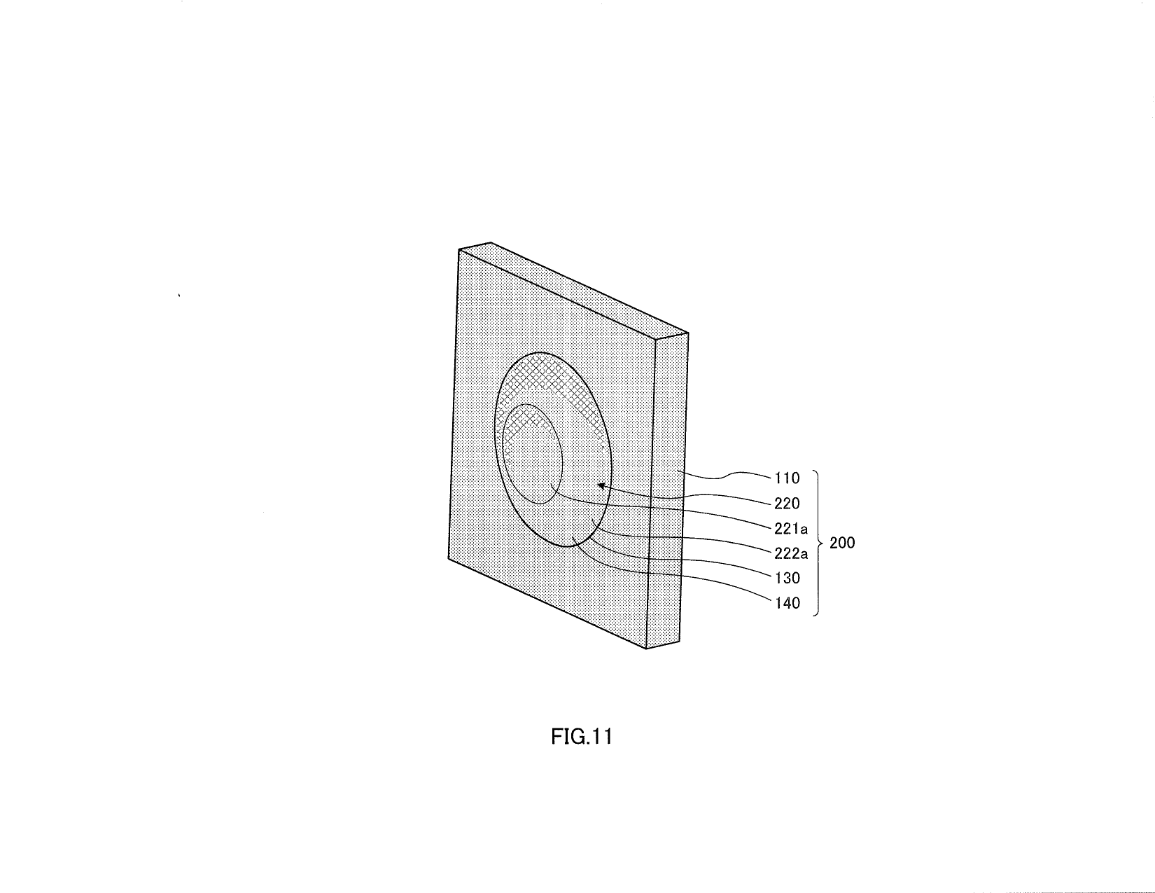

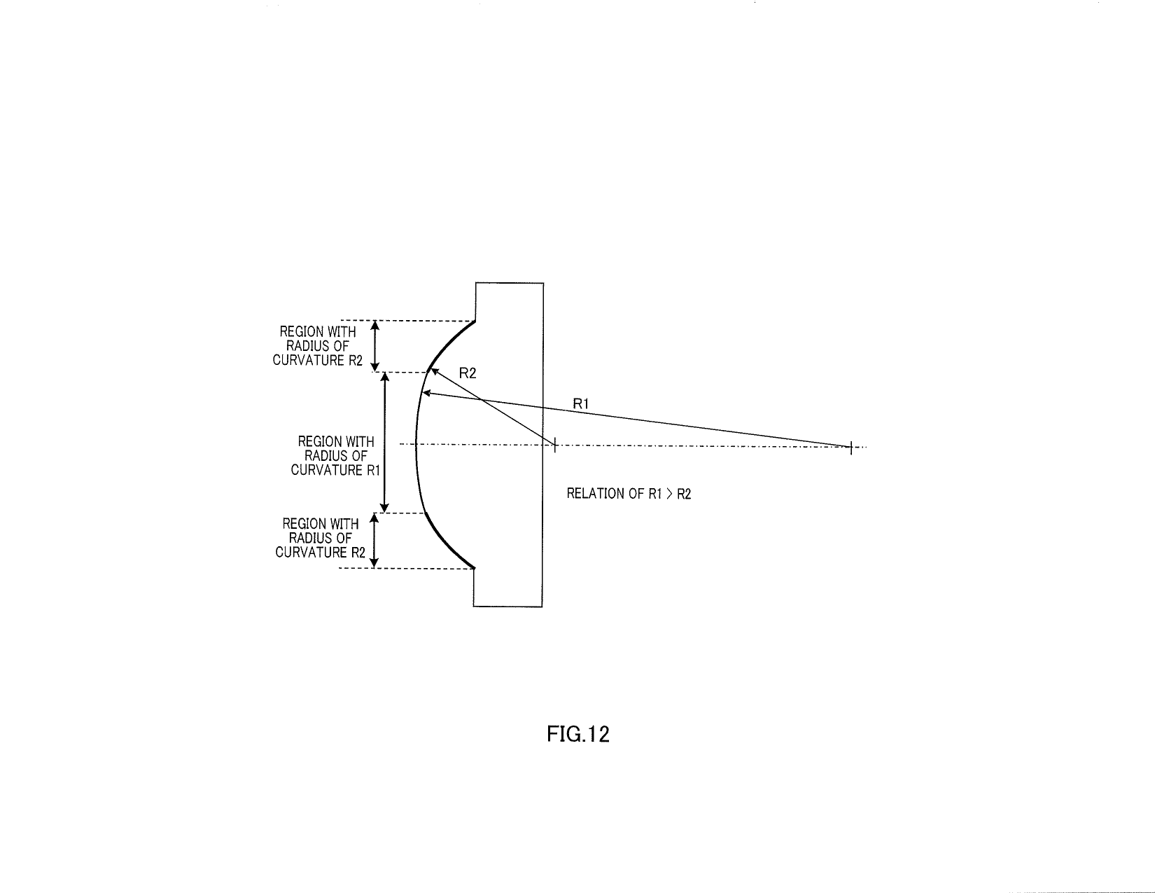

FIG. 11 is a perspective view illustrating an output mirror of a laser light source apparatus according to Embodiment 2 of the claimed invention. FIG. 12 is a cross-sectional view illustrating the output mirror of FIG. 11. The same components as those in FIG. 2 are appended by the same reference signs, and any overlapping description is omitted.

As illustrated in FIG. 11 and FIG. 12, output mirror 200 is a convex lens mirror having multiple radii of curvature.

Output mirror 200 can be used instead of output mirror 100 (see FIG. 3) according to Embodiment 1.

Output mirror 200 includes: base part 110 formed of the glass substrate; circular convex part 220 that is formed in base part 110 by dry etching and has multiple radii of curvature; groove 130 that is formed in base part 110 around convex part 220 while the dry etching proceeds; and film 140 formed on convex surface 221a and convex surface 222a of convex part 220. Further, output mirror 200 has a rear surface that is not convex, but flat; and a film that is formed on the rear surface, which provides the function of antireflectivity at a wavelength of 1,064 nm and a wavelength of 532 nm.

Groove 130 has a depth and a width that are different depending on etching conditions and the radius of curvature of a resist. For example, groove 130 has an approximate depth of 1 μm or less and a width of several tens of micrometers or less.

Film 140 provides a function of high reflectivity to a fundamental wavelength laser beam with a wavelength of 1,064 nm and provides a function of antireflectivity to a half-wavelength laser beam with a wavelength of 532 nm.

Convex part 220 has a convex shape that cannot actually be distinguished by naked eyes, similarly to convex part 120 of output mirror 100 of Embodiment 1.

As illustrated in FIG. 12, convex part 220 includes: convex surface 221a having a region with a large radius of curvature (radius of curvature R1) in an optical axis central portion; and convex surface 222a having a region with a small radius of curvature (radius of curvature R2; R1>R2) around convex surface 221a. Convex part 220 has a radius of curvature that is discontinuous at a boundary between convex surface 221a that has the radius of curvature R1 and convex surface 222a that has the radius of curvature R2.

Hereinafter, an operation of output mirror 200 configured as described above will be described.

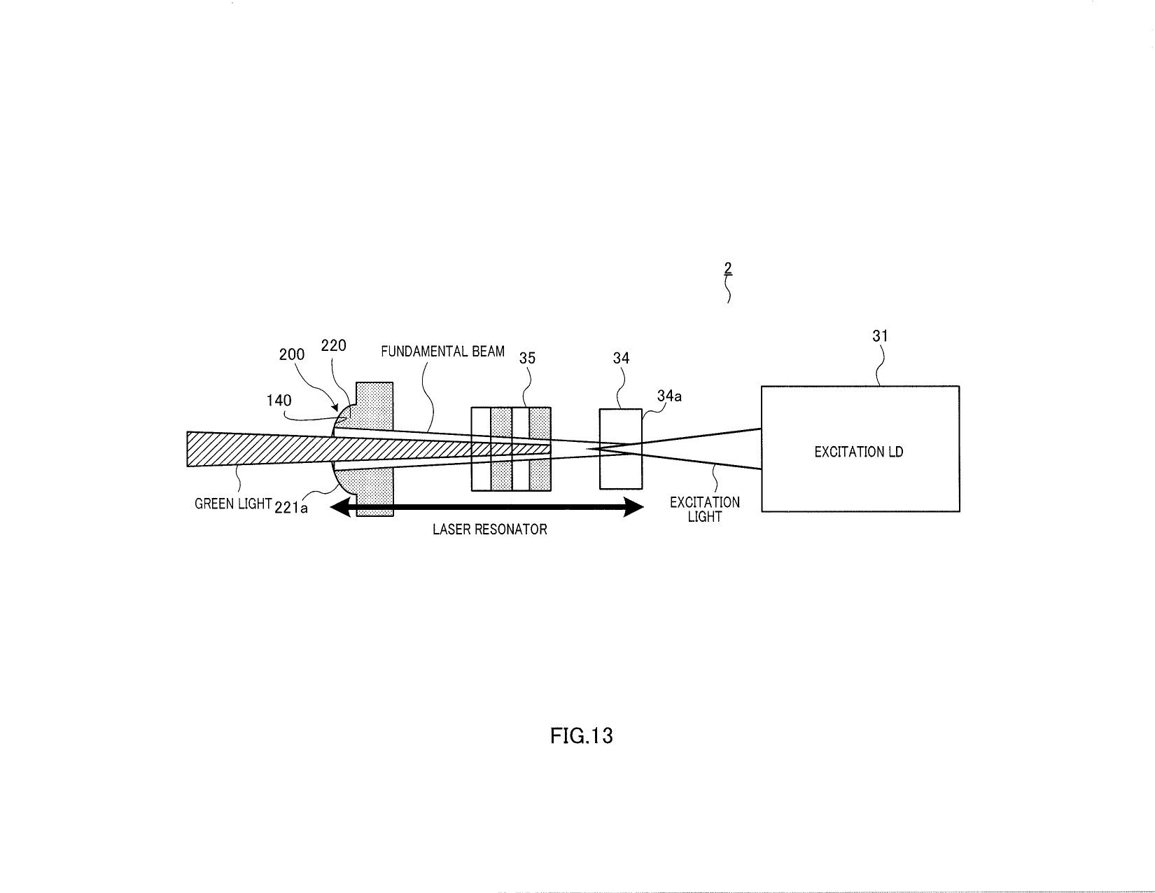

FIG. 13 is a schematic view for describing an operation of a green laser light source apparatus including output mirror 200. Because FIG. 13 is a schematic view describing the operation, for ease of the description the configuration of FIG. 3 has been illustrated in a simplified manner in FIG. 13.

As illustrated in FIG. 13, green laser light source apparatus 2 includes: semiconductor laser 31 that outputs the excitation laser beam; solid-state laser element 34 that is a laser medium; wavelength converter element 35; and output mirror 200.

Output mirror 200 is installed so that convex part 220 is located on the side opposite to the side facing wavelength converter element 35. Using this configuration, a laser resonator is formed between film 34a of solid-state laser element 34 and film 140 formed on convex surface 221a of output mirror 200, and the fundamental wavelength laser beam with a wavelength of 1,064 nm is resonated and amplified.

In general, as the excitation is increased, the fundamental beam becomes larger. As the fundamental beam becomes larger, the oscillation mode is disturbed, and the laser is oscillated in various states. In order to stabilize the oscillation state, it is necessary to suppress the fundamental beam from becoming larger.

In the present embodiment, convex part 220 of output mirror 200 includes convex surface 221a having the radius of curvature R1 and convex surface 222a having the radius of curvature R2, and convex part 220 has a radius of curvature that is discontinuous at the boundary therebetween. This configuration enables the fundamental beam that has entered convex surface 222a having the radius of curvature R2 to be reflected in a direction off wavelength converter element 35. As a result, spreading of the diameter of the fundamental beam can be suppressed, whereby disturbance of the oscillation mode can be suppressed.

Hereinafter, the above embodiment will be described more in greater detail. As illustrated in FIG. 13, the fundamental beam that has entered convex surface 221a having the radius of curvature R1 is resonated and amplified between film 34a of solid-state laser element 34 and film 140 formed on convex surface 221a of convex surface 221a having the radius of curvature R1. In contrast, the fundamental beam that has entered convex surface 222a having the radius of curvature R2 is reflected in a direction off wavelength converter element 35. Accordingly, spreading of the diameter of the fundamental beam can be suppressed, and the beam in a single mode can be obtained. By obtaining a single-mode beam, the beam can be condensed to approach its diffraction limit. In other words, an effect is achieved in which spreading is suppressed in a lateral-mode at the time the single-mode is obtained.

Next, a method of manufacturing output mirror 200 will be described.

In the present embodiment, convex part 220 of output mirror 200 includes convex surface 221a having the radius of curvature R1 and convex surface 222a having the radius of curvature R2. The inventors of the claimed invention discovered that the convex lens having multiple radii of curvature could be easily achieved by changing etching conditions during the dry etching process.

For example, a convex lens having multiple radii of curvature can be formed by selectively changing the plasma power or gas that is used in dry etching. Specifically, a more powerful dry etching using argon is first performed on form convex surface 222a having the radius of curvature R2, and less powerful dry etching (i.e., low plasma power and/or using a non-argon gas) is then performed to form convex surface 221a having radius of curvature R1.

The other manufacturing steps are similar to those in the manufacturing method according to Embodiment 1 illustrated in FIGS. 5A to 5H.

In the present embodiment, because convex part 220 of output mirror 200 includes convex surface 221a having the radius of curvature R1 and convex surface 222a having the radius of curvature R2, spreading of the diameter of the fundamental beam can be suppressed, a single-mode beam can be obtained, and the beam can be condensed to approach its diffraction limit.

Further, in the present embodiment, convex part 220 having the multiple radii of curvature can be easily formed by changing etching conditions during the dry etching process.

### Embodiment 3

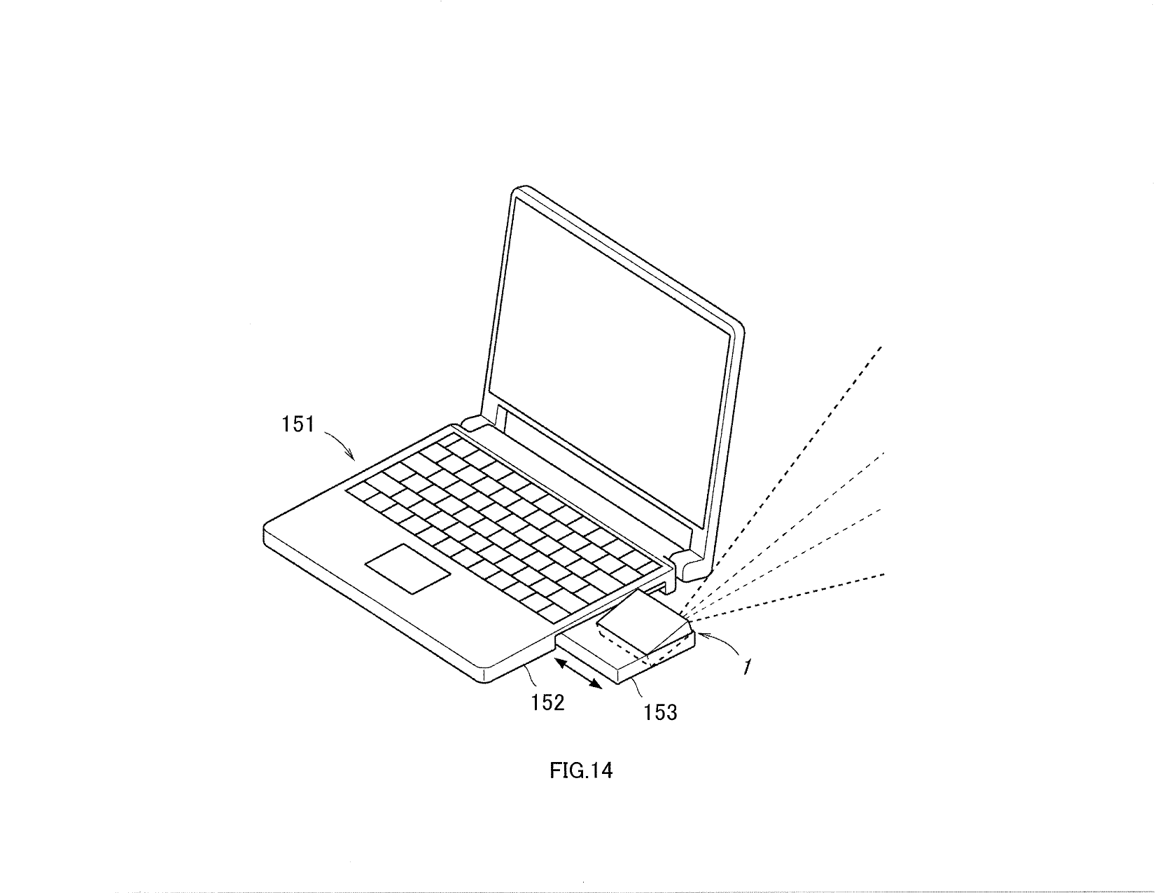

FIG. 14 is a perspective view illustrating an example in which an image display apparatus including a laser light source apparatus according to Embodiment 3 of the claimed invention is built in a notebook information processing apparatus.

As illustrated in FIG. 14, a housing space is formed on the rear side of a keyboard in casing 152 of information processing apparatus 151. Image display apparatus 1 can be freely housed in and pulled out of the housing space. Image display apparatus 1 is housed in casing 152 when not being used, and is pulled out of casing 152 when being used. A laser beam from image display apparatus 1 can be projected onto a screen during usage, by rotating image display apparatus 1 during usage to a predetermined angle with respect to base part 153 that rotatably supports image display apparatus 1.

### Embodiment 4

In the present embodiment, output mirror 100 having the convex surface illustrated in FIG. 2 or output mirror 200 illustrated in FIG. 11 is similarly applied to each of collimator lenses 11 to 13 of the respective color laser beams in FIG. 1, in addition to the abovementioned green laser light source apparatus 2 in FIG. 1. In the present case, LED light source apparatuses may be used for the light source apparatuses that output the respective color laser beams, instead of laser light source apparatuses 2 to 4.

The optical axis adjustment is necessary for light source apparatuses 2 to 4, whether each light source apparatus mounted on image display apparatus 1 illustrated in FIG. 1 is a laser light source apparatus or an LED light source apparatus. Accordingly, an output characteristic graph similar to that illustrated in FIG. 9 is obtained at the time of optical axis adjustment. In other words, the light output when the light beam output from each light source enters the central portion of groove 130 of the convex mirror illustrated in FIG. 2 appears as a point of inflection illustrated in a sharp wedge-like graph. However, output mirror 100 or 200 used as collimator lenses 11 to 13 is not moved for optical axis adjustment, unlike the case where output mirror 100 or 200 is applied to green laser light source apparatus 2 such as that according to Embodiment 1. In the present embodiment, light source apparatuses 2 to 4 are moved for the optical axis adjustment instead of moving the output mirror.

Accordingly, if groove 130 of output mirror 100 illustrated in FIG. 2 overlaps with a region of the light beam of each of light source apparatuses 2 to 4, the light output shows a characteristic change, and appears as a point of inflection. The relative movement direction and the relative amount of movement between each of light source apparatuses 2 to 4 and output mirror 100 used as collimator lenses 11 to 13 can be determined by detecting this point of inflection. In other words, by detecting this point of inflection, a person adjusting the optical axis would be able to recognize that the optical axis of each of light source apparatuses 2 to 4 significantly deviates from the adjustment range, and thus immediately be able to make a readjustment in the opposite direction. Thus, the optical axis adjustment of light source apparatuses 2 to 4 is extremely easy. The same applies when output mirror 200 illustrated in FIG. 11 is applied to collimator lenses 11 to 13.

The preferred exemplary embodiments of the claimed invention are described above. The scope of the claimed invention is not limited thereto.

In the abovementioned embodiments, the terms an optical component, a laser light source apparatus, an image display apparatus, and a method of manufacturing the laser light source apparatus are merely used in order to simplify the above descriptions, and thus may also be regarded as a laser light output apparatus, a method of manufacturing a semiconductor apparatus, and/or the like.

Further, in the above-mentioned embodiments, laser chip 41, solid-state laser element 34 and wavelength converter element 35 of green laser light source apparatus 2 respectively output the excitation laser beam with a wavelength of 808 nm, the fundamental wavelength laser beam (infrared laser beam) with a wavelength of 1,064 nm, and the half-wavelength laser beam (green laser beam) with a wavelength of 532 nm. However, the present invention is not specifically limited thereto. The laser beam that is ultimately output from green laser light source apparatus 2 may be recognized as being green. For example, a laser beam in a wavelength region with a peak wavelength of 500 nm to 560 nm may be output.

Further, a description regarding an example in which the image display apparatus according to the claimed invention is applied to the notebook information processing apparatus is disclosed in Embodiment 3. However, the image display apparatus according to the claimed invention may be applied to any electronic device as long as the electronic device includes the laser light source apparatus according to the claimed invention.

Moreover, the respective steps (e.g., resist application step) included in the method of manufacturing the laser light source apparatus, the type of gas that is used and conditions of dry etching, and/or the like are not specifically limited to those adopted in the above-mentioned embodiments.

The contents disclosed in the specification, drawings, and abstract of Japanese Patent Application No. 2012-002902 filed on Jan. 11, 2012 are all incorporated herein by reference.

What is claimed is:

1. An optical component comprising:
a base part formed of a glass substrate;
a convex part that is formed in the base part by dry etching; and
a groove that is formed in the base part around the convex part while the dry etching proceeds.

2. A laser light source apparatus comprising:
a semiconductor laser that outputs an excitation laser beam;
a solid-state laser element that is excited by the excitation laser beam, to thereby output a fundamental laser beam; and
an output mirror that forms a resonator together with the solid-state laser element, wherein
the output mirror comprises the optical component according to claim 1, the optical component comprising the convex part having a convex surface on which a film is formed.

3. The laser light source apparatus according to claim 2, wherein
the output mirror comprises the convex part having different radii of curvature.

4. The laser light source apparatus according to claim 3, wherein
the convex part comprises: a first convex surface having a region with a radius of curvature R1 in an optical axis central portion; and a second convex surface having a region with a radius of curvature R2 (R1>R2) around the first convex surface.

5. The laser light source apparatus according to claim 4, wherein
the convex part has a radius of curvature that is discontinuous at a boundary between the first convex surface and the second convex surface.

6. The laser light source apparatus according to claim 2, further comprising a wavelength converter element that converts a wavelength of the fundamental laser beam output from the solid-state laser element, to thereby output a green laser beam.

7. An image display apparatus comprising the laser light source apparatus according to claim 2.

8. An image display apparatus comprising:
a plurality of light sources;
a collimator lens that converts light beams output from the light sources into parallel beams;
a relay optical system that guides the parallel beams into the same optical path;
a spatial light modulator that modulates the light beam output from the relay optical system;
a projection optical system that projects the light beam modulated by the spatial light modulator to the outside of the apparatus; and
a casing that supports the plurality of light sources, the collimator lens, the relay optical system, the spatial light modulator, and the projection optical system, wherein
the collimator lens includes the optical component according to claim 1.

9. A method of manufacturing an optical component, comprising:
applying a resist to a glass substrate; and
performing dry etching on the glass substrate that has been coated by the resist, to thereby form a convex part via the resist.

10. The method of manufacturing an optical component according to claim 9, wherein
the dry etching comprises forming a groove around the convex part.

11. The method of manufacturing an optical component according to claim 9, wherein
the dry etching comprises forming a convex part having multiple radii of curvature by changing etching conditions during the dry etching.

12. A method of manufacturing a laser light source apparatus, the laser light source apparatus including a semiconductor laser that outputs an excitation laser beam, a solid-state laser element that is excited by the excitation laser beam, to thereby output a fundamental laser beam, a wavelength converter element that converts a wavelength of the fundamental laser beam to output a half-wavelength laser beam, an output mirror including a convex part, a groove formed around the convex part and a film formed on a convex surface of the convex part, so that the output mirror forms a resonator together with the solid-state laser element and a base that holds at least the output mirror, the method comprising:
attaching the output mirror to the base, wherein
the attaching includes:
installing the output mirror on the base;
measuring a laser output of the half-wavelength laser beam at a position of the installed output mirror; and
determining an attachment position of the output mirror on a basis of a measurement result of the laser output when the half-wavelength laser beam is incident on the groove.
